(19) United States
(12) Patent Application Publication
(10) Pub. No.: US 2011/0095820 A1
(43) Pub. Date: Apr. 28, 2011

(54) METHOD FOR PRE-DISTORTING A POWER AMPLIFIER AND THE CIRCUIT THEREOF

(75) Inventors: WEN SHENG HOU, HSINCHU COUNTY (TW); GUAN HENRY LIN, HSINCHU COUNTY (TW)

(73) Assignee: RALINK TECHNOLOGY CORPORATION, HSINCHU COUNTY (TW)

(21) Appl. No.: 12/909,132

(22) Filed: Oct. 21, 2010

(30) Foreign Application Priority Data
Oct. 23, 2009 (TW) 098135880

(51) Int. Cl. H03F 1/26

(52) U.S. Cl. 330/149

(57) ABSTRACT

A method for pre-distorting a power amplifier comprises the steps of: inputting a baseband digital training signal with time-varying amplitude into a transmitting end in a single operation; converting the baseband digital training signal to a radio-frequency analog training signal, and converting the radio-frequency analog training signal to a radio-frequency analog transmitting signal via a power amplifier; receiving the radio-frequency analog transmitting signal at a receiving end, and converting the received signal to a baseband digital receiving signal; and calculating parameters for pre-distorting the power amplifier by estimating the characteristic curve of the power amplifier according to the baseband digital receiving signal.

### BACKGROUND OF THE INVENTION

1. Field of the Invention

The present invention relates to a pre-distorting method, and more particularly, to a method for pre-distorting a power amplifier.

2. Description of the Related Art

A typical wireless communication chip comprises two parts: a baseband signal processing module and a radio frequency signal processing module. The baseband signal processing module is configured to process a digital signal to be transmitted or a digital signal already received. The radio frequency signal processing module is configured to convert a baseband digital signal to be transmitted to an analog radio frequency signal for the subsequent transmission operation, or to convert a received analog radio frequency signal to a baseband digital signal for the subsequent processing operation of the baseband signal processing module.

A typical radio frequency signal processing module comprises a power amplifier, which is configured to amplify an analog radio frequency signal, which then can be transmitted via an antenna. Power amplifiers can be categorized as linear power amplifiers and non-linear power amplifiers. The ratio of the output signal and the input signal of a linear power amplifier is a constant value, while the ratio of the output signal and the input signal of a non-linear power amplifier is not. That is, the output signal of a non-linear power amplifier is distorted. However, a non-linear power amplifier has better output power efficiency than a linear power amplifier. In other words, for outputting signals of the same power, a linear power amplifier will consume more energy than a non-linear power amplifier. Therefore, to achieve low power consumption, most communication systems apply non-linear power amplifiers.

FIG. 1 shows the relationship between the amplitude of an output signal and the amplitude of the corresponding input signal of a non-linear power amplifier, i.e. the AM/AM conversion characteristic of the non-linear power amplifier. As shown in FIG. 1, the non-linear power amplifier performs gain compression and power saturation functions. That is, when the amplitude of an input signal of the non-linear power amplifier is low, the non-linear power amplifier acts as a linear power amplifier. However, as the amplitude of an input signal of the non-linear power amplifier increases, the non-linear characteristic becomes more obvious. FIG. 2 shows the to relationship between the phase of an output signal and the amplitude of the corresponding input signal of a non-linear power amplifier, i.e. the AM/PM conversion characteristic of the non-linear power amplifier. As shown in FIG. 2, the phase of the output signal shifts as the amplitude of the corresponding input signal becomes greater.

To reduce the non-linear distortion effect on the output signal of a non-linear power amplifier, it is usually preferred to operate a non-linear power amplifier in the linear state. That is, it is usually preferred to reduce the maximum amplitude of the input signal of a non-linear power amplifier. However, this approach trades efficiency for linearity. Another approach to achieve linearity is to pre-distort the non-linear power amplifier. Typical pre-distorting methods for a non-linear power amplifier comprise baseband digital pre-distorting methods and radio frequency/intermediate frequency analog pre-distorting methods. Unlike radio frequency/intermediate frequency analog pre-distorting methods, a baseband digital pre-distorting method does not need an additional analog circuit.

Most current baseband digital pre-distorting methods use the least mean square (LMS) algorithm. However, LMS has the disadvantages of slow pre-distortion speed and design complexity. Accordingly, there is a need to provide a method for pre-distorting a power amplifier which can achieve linearity for a non-linear power amplifier by baseband digital pre-distorting in a fast and efficient manner.

### SUMMARY OF THE INVENTION

The method for pre-distorting a power amplifier according to one embodiment of the present invention comprises the steps of: inputting a baseband digital training signal with time-varying amplitude into a transmitting end in a single operation; converting the baseband digital training signal to a radio-frequency analog training signal, and converting the radio-frequency analog training signal to a radio-frequency analog transmitting signal via a power amplifier; receiving the radio-frequency analog transmitting signal at a receiving end and converting the received to signal to a baseband digital receiving signal; and calculating parameters for pre-distorting the power amplifier by estimating the characteristic curve of the power amplifier according to the baseband digital receiving signal.

The circuit for pre-distorting a power amplifier according to one embodiment of the present invention comprises a transmitting end baseband part, a transmitting end radio frequency part, a receiving end radio frequency part and a receiving end baseband part. The transmitting end baseband part comprises a look-up table to store parameters for pre-distorting a power amplifier and is configured to receive a baseband digital signal. The transmitting end radio frequency part comprises the power amplifier and is configured to process an output signal of the transmitting end baseband part. The receiving end radio frequency part comprises a measurer to estimate the characteristic curve of the power amplifier, and is configured to receive a signal via an antenna. The receiving end baseband part is configured to process an output signal of the receiving end radio frequency part.

The foregoing has outlined rather broadly the features and technical advantages of the present invention in order that the detailed description of the invention that follows may be better understood. Additional features and advantages of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention will become apparent upon reading the following description and upon referring to the accompanying drawings of which:

to FIG. 1 shows the relationship between the amplitude of an output signal and the amplitude of the corresponding input signal of a non-linear power amplifier;

FIG. 2 shows the relationship between the phase of an output signal and the amplitude of the corresponding input signal of a non-linear power amplifier;

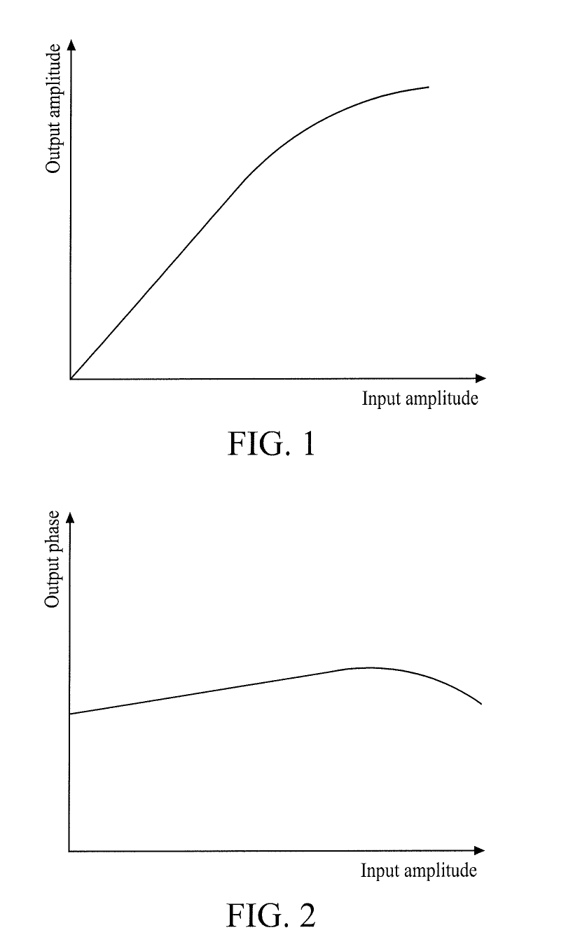

FIG. 3 shows a transceiver circuit according to an embodiment of the present invention;

FIG. 4 shows a flowchart of the method for pre-distorting a power amplifier according to an embodiment of the present invention;

FIG. 5 shows the amplitude of a baseband training signal according to an embodiment of the present invention; and

FIG. 6 shows the relationship of a pre-distorter and pre-distorting parameters stored in a look-up table according to an embodiment of the present invention.

### DETAILED DESCRIPTION OF THE INVENTION

For the method for pre-distorting a non-linear power amplifier using LMS algorithm, a training signal is inputted to the transmitter end of the baseband part of a transceiver. After the training signal feeds back from the receiving end of the transceiver, the parameters of a look-up table are adjusted, and another training signal is inputted. However, there is downtime between each input of the training signals. Such downtime slows down the pre-distortion speed, and renders the phases of the training signals uncontrollable. In addition, since the pre-distorting time is long, the final work environment of the non-linear power amplifier may be different from the initial work environment of the non-linear power amplifier. For example, the final operation temperature of the non-linear power amplifier may be tens of degrees higher than the initial operation temperature of the non-linear power amplifier, which may cause pre-distortion error.

The method for pre-distorting a power amplifier of the present invention directly measures the AM/AM conversion characteristic and the AM/PM conversion characteristic of the power amplifier and inputs all of the training signals in one input operation. Therefore, there is no downtime between each input of the training signals. In addition, since the measuring procedure takes only a small amount of time, there is little or no change to the work environment of the power amplifier, and thus the linearity of the power amplifier can be achieved.

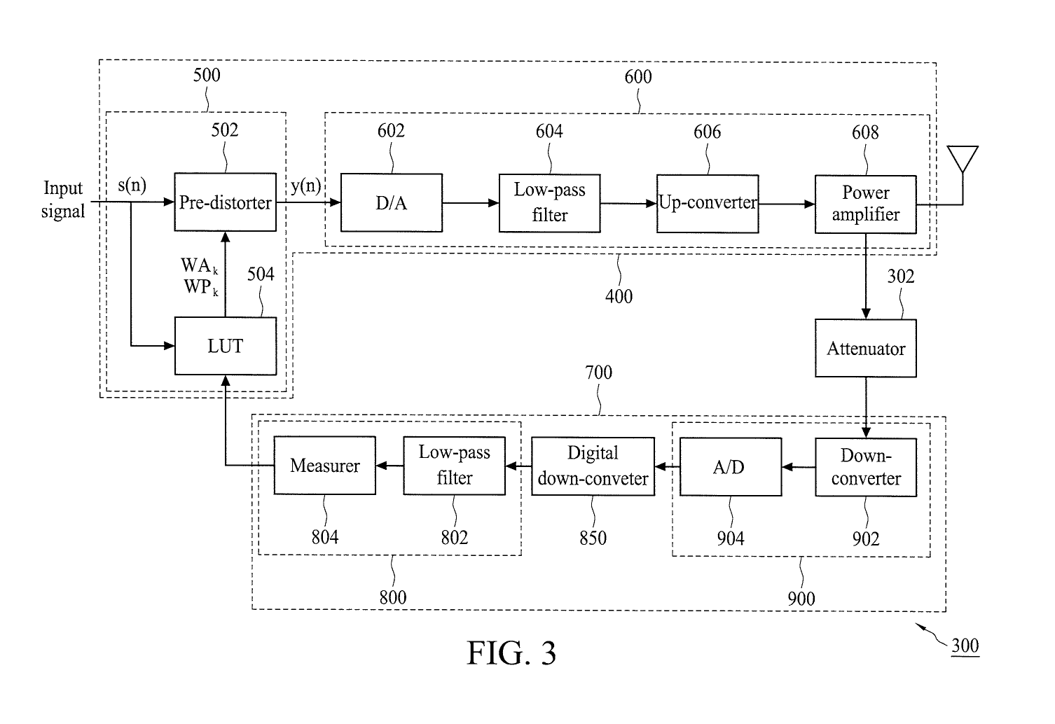

FIG. 3 shows a transceiver circuit according to an embodiment of the present invention. As shown in FIG. 3, the transceiver circuit 300 comprises a transmitting end 400, a receiving end 700 and an attenuator 302. The transmitting end 400 can be divided into two parts: a baseband part 500 and a radio frequency (RF) part 600. The baseband part 500 is configured to receive a baseband digital signal, process the baseband digital signal, and then deliver it to the RF part 600. The RF part 600 is configured to emit the processed signal via an antenna. Similarly, the receiving end 700 can be divided into three parts: a baseband part 800, a digital down-converting part 850 and an RF part 900. The RF part 900 receives a signal via an antenna, converts it to a digital signal and delivers it to the digital down-converting part 850. The digital down-converting part 850 converts the digital signal to a DC location and then delivers it to the baseband part 800 for signal processing.

The baseband part 500 comprises a pre-distorter 502 and a look-up table (LUT) 504. The RF part 600 comprises a digital-to-analog converter 602, a first low-pass filter 604, an up-converter 606 and a power amplifier 608. The RF part 900 comprises a down-converter 902 and an analog-to-digital converter 904. The baseband part 800 comprises a second low-pass filter 802 and a measurer 804.

As shown in FIG. 3, the transceiver circuit 300 is configured to find the corresponding parameters of a baseband digital signal s(n) according to the LUT 504. The pre-distorter 502 is configured to pre-distort the baseband digital signal s(n) by the corresponding parameters and output a pre-distorted signal y(n). The pre-distorted signal y(n) is then converted to an analog signal by the digital-to-analog converter 602. The first low-pass filter 604 is configured to filter the analog signal. The up-converter 606 is configured to up-convert the filtered analog signal to an RF frequency band. The power amplifier 608 is configured to amplify the up-converted analog signal to be emitted by an antenna. Since the parameters stored in the LUT 504 are the compensation parameters designed particularly for the AM/AM conversion characteristic and the AM/PM conversion characteristic of the power amplifier 608, the pre-distorting procedure can be performed in a digital signal processing manner. Accordingly, the linearity of the power amplifier 608 can be achieved. Such pre-distorting method can be implemented in a baseband digital signal processing manner under the original RF architecture without an additional analog processing circuit. Meanwhile, the approach of pre-distorting in a baseband digital signal processing manner is more versatile, and can be integrated with the baseband system more easily.

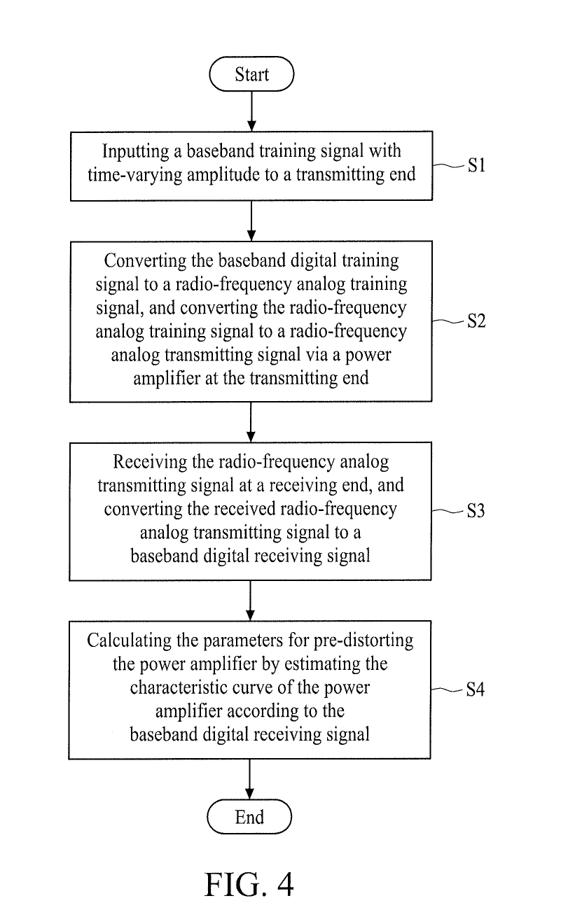

FIG. 4 shows a flowchart of a method for pre-distorting a power amplifier according to an embodiment of the present invention. In step S1, a baseband training signal with time-varying amplitude is inputted to a transmitting end, and step S2 is executed. Preferably, the baseband digital training signal is a training signal with monotone, and the amplitude of the baseband digital training signal covers the input range of the power amplifier. In step S2, the baseband digital training signal is converted to a radio-frequency analog training signal, and the radio-frequency analog training signal is converted to a radio-frequency analog transmitting signal via a power amplifier at the transmitting end, and step S3 is executed. In step S3, the radio-frequency analog transmitting signal is received at a receiving end, and the received radio-frequency analog transmitting signal is converted to a baseband digital receiving signal, and step S4 is executed. In step S4, the parameters for pre-distorting the power amplifier are calculated by estimating the characteristic curve of the power amplifier according to the baseband digital receiving signal.

Referring to FIG. 3, the method shown in FIG. 4 can be followed to establish the parameters for a pre-distorting nonlinear effect of the power amplifier 608 stored in the LUT 504. In step S1, a baseband training signal with time-varying amplitude is inputted to the baseband part 500. Since the parameters for pre-distorting nonlinear effect of the power amplifier 608 are not yet obtained, the amplitude and phase of the baseband training signal are not altered by the pre-distorter 502. In step S2, the baseband digital training signal is converted to a radio-frequency analog training signal by the digital-to-analog converter 602. The radio-frequency analog training signal is then converted to a radio-frequency analog transmitting signal via the first low-pass filter 604, the up-converter 606 and the power amplifier 608. In step S3, the radio-frequency analog transmitting signal is fed back to the RF part 900 via the attenuator 302. The received radio-frequency analog transmitting signal is then converted to a baseband digital receiving signal via the down-converter 902, the analog-to-digital converter 904, the digital down-converting part 850 and the second low-pass filter 802. Preferably, the second low-pass filter 802 is a cascaded integrator comb filter. In step S4, the measurer 804 calculates the parameters for pre-distorting the power amplifier 608, i.e. the parameters for pre-distorting the power amplifier 608 stored in the LUT 504, by estimating the characteristic curve of the power amplifier 608 according to the baseband digital receiving signal.

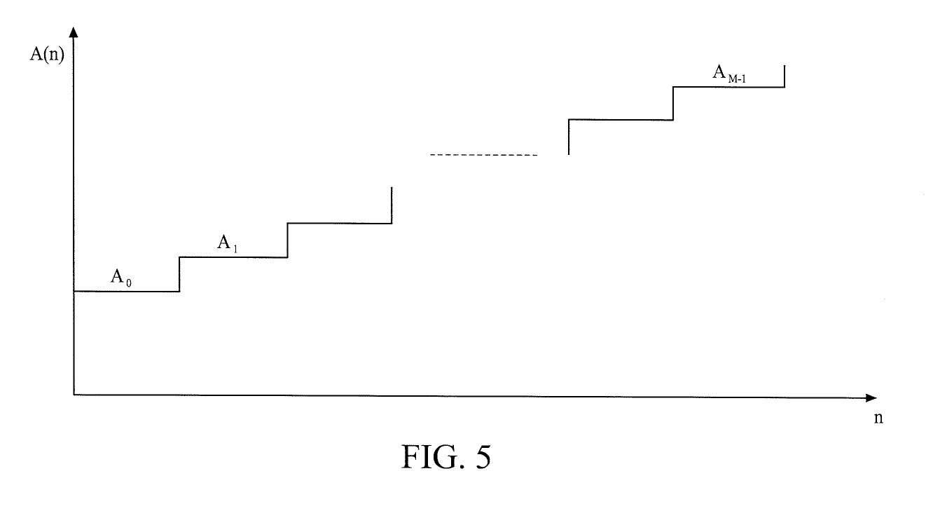

FIG. 5 shows the amplitude of the baseband training signal. As shown in FIG. 5, the amplitude of the baseband training signal A(n) comprises M different values: A₀ to A_{M-1}, which increase stepwise and cover the input range of the power amplifier 608. The input signal of the measurer 804 is rₖ(n). The characteristic curve of the power amplifier 608 can be estimated as follows:

The AM/AM conversion characteristic: Bₖ=abs{rₖ(n)}

The AM/PM conversion characteristic: Dₖ=angle{rₖ(n)*conj{r₀(n)}}, wherein k is an integer ranging from 0 to M−1.

The loop gain of the transceiver circuit 300 can be estimated from the linear region as follows: G=B₀/A₀. The parameters for pre-distorting the AM/AM conversion characteristic and the AM/PM conversion characteristic of the power amplifier 608 for the baseband training signal A(n) are WAₖ and WPₖ, which can be obtained as follows:

```
Bₘₐₓ=max{B₀ , B₁ , ... , B_{M-1}};
for (k=0:M−1)
  Bₖ′=G*Aₖ
  if (Bₘₐₓ<= Bₖ′)
    Aₖ′= Bₘₐₓ;
    Dₖ′= Dₘₐₓ;
  else
    search N with B_{N}<=Bₖ′<= B_{N+1};
    Aₖ′=interpolator{A_{N} , A_{N+1}};
    Dₖ′=interpolator{D_{N} , D_{N+1}};
  end
  WAₖ=Aₖ′/Aₖ;
  WPₖ=Dₖ′;
end
```

wherein search is a searching procedure, and interpolator is an interpolating procedure. According to the above pseudo code, for those input amplitudes Aₖ, which after the linear amplification of the power amplifier 608 would correspond to output amplitudes exceeding the maximum output amplitude Bₘₐₓ, the amplitude pre-distorting values stored in the LUT 504 are Aₘₐₓ/Aₖ, wherein Aₘₐₓ is the input amplitude corresponding to the maximum output amplitude Bₘₐₓ of the power amplifier 608. The phase pre-distorting value stored in the LUT 504 is Dₘₐₓ, which corresponds to the phase shifts of the maximum output amplitude Bₘₐₓ of the power amplifier 608.

For those input amplitudes Aₖ, which after the linear amplification of the power amplifier 608 do not exceed the maximum output amplitude Bₘₐₓ, the amplitude pre-distorting values stored in the LUT 504 are estimated according to an interpolation calculation. In one embodiment of the present invention, a linear interpolation calculation is implemented as follows:

Aₖ′=interpolator{A_{N},A_{N+1}}=A_{N}+(A_{N+1}−A_{N})*(Bₖ′−B_{N})/(B_{N+1}−B_{N})

Dₖ′=interpolator{D_{N},D_{N+1}}=D_{N}+(D_{N+1}−D_{N})*(Bₖ′−B_{N})/(B_{N+1}−B_{N})

In another embodiment of the present invention, the nearest points can be stored instead to simplify the calculation process as follows:

Aₖ′=A_{N}, if (Bₖ′−B_{N})<=(B_{N+1}−Bₖ′)

Aₖ′=A_{N+1}, otherwise

Dₖ′=D_{N}, if (Bₖ′−B_{N})<=(B_{N+1}−Bₖ′)

Dₖ′=D_{N+1}, otherwise

Accordingly, if the input signal of the transceiver circuit 300 is s(n), the pre-distorted signal y(n) after the pre-distorter 502 can be represented as follows: y(n)=s(n)·WAₖ·exp(−j·WPₖ), if |s(n)|εentry k

As shown in the above equation, the pre-distorting parameter WAₖ serves to adjust the amplitude of the input signal of the transceiver circuit 300 s(n), and the pre-distorting parameter WPₖ serves to adjust the phase of the input signal of the transceiver circuit 300 s(n).

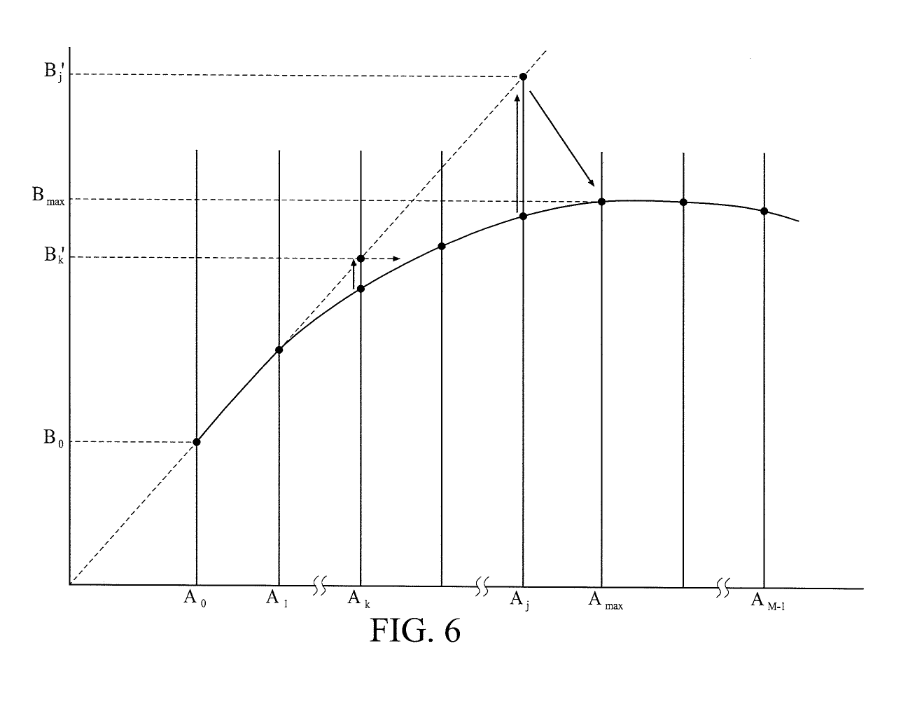

FIG. 6 shows the relationship between the pre-distorter 502 and the pre-distorting parameters stored in the LUT 504. As shown in FIG. 6, the maximum output amplitude of the power amplifier 608 is Bₘₐₓ, and the corresponding input amplitude is Aₘₐₓ. If the linear amplification G*Aₖ of the power amplifier 608 for an input signal with amplitude Aₖ exceeds the maximum output amplitude Bₘₐₓ, the pre-distorter 502 adjusts the amplitude of the input signal to Aₘₐₓ. If the linear amplification G*Aₖ of the power amplifier 608 for an input signal with amplitude Aₖ does not exceed the maximum output amplitude Bₘₐₓ, the pre-distorter 502 adjusts the amplitude of the input signal by interpolation calculation.

In conclusion, the method for pre-distorting a power amplifier of the present invention measures the AM/AM conversion characteristic and the AM/PM conversion characteristic of the power amplifier directly and inputs all of the training signals in one input operation. Therefore, there is no downtime between each input of the training signals. Such input manner can simplify the phase control. In addition, since the measuring procedure takes only a small amount of time, there is little or no changes to the work environment of the power amplifier, and thus the linearity of the power amplifier can be achieved. Furthermore, the method for pre-distorting a power amplifier of the present invention can be implemented on the circuit board directly without considering the differences between individual power amplifiers.

Although the present invention and its advantages have been described in detail, it should be understood that various changes, substitutions and alterations can be made herein without departing from the spirit and scope of the invention as defined by the appended claims. For example, many of to the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for pre-distorting a power amplifier, comprising the steps of:
inputting a baseband digital training signal with time-varying amplitude into a transmitting end in a single operation;
converting the baseband digital training signal to a radio-frequency analog training signal, and converting the radio-frequency analog training signal to a radio-frequency analog transmitting signal via a power amplifier;
receiving the radio-frequency analog transmitting signal at a to receiving end, and converting the received signal to a baseband digital receiving signal; and
calculating parameters for pre-distorting the power amplifier by estimating the characteristic curve of the power amplifier according to the baseband digital receiving signal.

2. The method of claim 1, wherein the baseband digital training signal is a training signal with monotone.

3. The method of claim 1, wherein the amplitude of the baseband digital training signal covers the input range of the power amplifier.

4. The method of claim 1, wherein the amplitude of the baseband digital training signal increases stepwise.

5. The method of claim 1, wherein the radio-frequency analog transmitting signal is attenuated before being received at the receiving end.

6. The method of claim 1, wherein a low-pass filter is utilized in the step of converting the received signal to the baseband digital receiving signal.

7. The method of claim 6, wherein the low-pass filter is a cascaded integrator comb filter.

8. The method of claim 1, wherein the transmitting end and the receiving end are installed in a transceiver.

9. The method of claim 1, wherein the parameters for pre-distorting the power amplifier comprise amplitude pre-distorting parameters and phase pre-distorting parameters.

10. The method of claim 9, wherein for those amplitude levels of the baseband digital training signal to be pre-distorted which after the linear amplification by the power amplifier would correspond to amplitude levels exceeding the maximum output amplitude of the power amplifier, the corresponding amplitude pre-distorting parameters are the ratios of the amplitude levels of the baseband digital training signal corresponding to the maximum output amplitude of the power amplifier and the amplitude levels of the baseband digital training signal to be pre-distorted, and the corresponding phase pre-distorting parameters are the phase shifts of the baseband digital training signal corresponding to the maximum output amplitude of the power amplifier caused by the power amplifier.

11. The method of claim 9, wherein for those amplitude levels of the baseband digital training signal to be pre-distorted which after the linear amplification by the power amplifier would not exceed the maximum output amplitude of the power amplifier, the corresponding amplitude pre-distorting parameters are the ratios of the amplitude levels of the baseband digital training signal corresponding to the linear amplification of the baseband digital training signal to be pre-distorted and the amplitude levels of the baseband digital training signal to be pre-distorted, and the corresponding phase pre-distorting parameters are the phase shifts of the baseband digital training signal corresponding to the linear amplification of baseband digital training signal to be pre-distorted caused by the power amplifier.

12. The method of claim 11, wherein the amplitude levels of the baseband digital training signal corresponding to the linear amplification of the baseband digital training signal to be pre-distorted are determined in an interpolation manner.

13. The method of claim 9, wherein for those amplitude levels of the baseband digital training signal to be pre-distorted which after the linear amplification by the power amplifier would not exceed the maximum output amplitude of the power amplifier, the corresponding amplitude pre-distorting parameters are the ratios of the amplitude levels of the baseband digital training signal closest to the amplitude levels of the baseband digital training signal corresponding to the linear amplification of the baseband digital training signal and the amplitude levels of the baseband digital training signal to be pre-distorted, and the corresponding phase pre-distorting parameters are the phase shifts of the baseband digital training signal with the amplitude levels closest to the amplitude levels of the baseband digital training signal corresponding to the linear amplification of the baseband digital training signal caused by the power amplifier.

14. The method of claim 1, which is to pre-distort the AM/AM conversion characteristic and the AM/PM conversion characteristic of the power amplifier.

15. A circuit for pre-distorting a power amplifier, comprising:
a transmitting end baseband part, configured to receive a baseband digital signal, comprising a look-up table to store parameters for pre-distorting a power amplifier;
a transmitting end radio frequency part, configured to process output signal of the transmitting end baseband part, comprising the power amplifier;
a receiving end radio frequency part, configured to receive a signal via an antenna, comprising a measurer to estimate the characteristic curve of the power amplifier; and
a receiving end baseband part, configured to process on output signal of the receiving end radio frequency part;
wherein the parameters are obtained according to a baseband digital training signal with time-varying amplitude passing through the transmitting end baseband part, the transmitting end radio frequency part, the receiving end radio frequency part and the receiving end baseband part.

16. The circuit of claim 15, wherein the parameters comprise amplitude pre-distorting parameters and phase pre-distorting parameters.

17. The circuit of claim 15, wherein for those amplitude levels of the baseband digital signal to be pre-distorted which after the linear amplification by the power amplifier would correspond to amplitude levels exceeding the maximum output amplitude of the power amplifier, the corresponding amplitude pre-distorting parameters stored in the look-up table are the ratios of the amplitude levels of the baseband digital signal corresponding to the maximum output amplitude of the power amplifier and the amplitude levels of the baseband digital signal to be pre-distorted, and the corresponding phase pre-distorting parameters stored in the look-up table are the phase shifts of the baseband digital signal corresponding to the maximum output amplitude of the power amplifier caused by the power amplifier.

18. The circuit of claim 15, wherein for those amplitude levels of the baseband digital signal to be pre-distorted which after the linear amplification by the power amplifier would not exceed the maximum output amplitude of the power amplifier, the corresponding amplitude pre-distorting parameters stored in the look-up table are the ratios of the amplitude levels of the baseband digital signal corresponding to the linear amplification of the baseband digital signal to be pre-distorted and the amplitude levels of the baseband digital signal to be pre-distorted, and the corresponding phase pre-distorting parameters are the phase shifts of the baseband digital signal corresponding to the linear amplification of baseband digital signal to be pre-distorted caused by the power amplifier.

19. The circuit of claim 18, wherein the amplitude levels of the baseband digital signal corresponding to the linear amplification of the baseband digital signal to be pre-distorted are determined in an interpolation manner.

20. The circuit of claim 15, wherein for those amplitude levels of the baseband digital signal to be pre-distorted which after the linear amplification by the power amplifier would not exceed the maximum output amplitude of the power amplifier, the corresponding amplitude pre-distorting parameters stored in the look-up table are the ratios of the amplitude levels of the baseband digital signal closest to the amplitude levels of the baseband digital signal corresponding to the linear amplification of the baseband digital signal and the amplitude levels of the baseband digital signal to be pre-distorted, and the corresponding phase pre-distorting parameters stored in the look-up table are the phase shifts of the baseband digital signal with the amplitude levels closest to the amplitude levels of the baseband digital signal corresponding to the linear amplification of the baseband digital signal caused by the power amplifier.
